(19) United States
(12) Patent Application Publication
(10) Pub. No.: US 2007/0205813 A1
(43) Pub. Date: Sep. 6, 2007

(54) Circuit and method for reducing jitter and/or phase jump problems in a clock amplifier device

(75) Inventor: Mikael Hjelm, Vaesteras (SE)

Correspondence Address: Maginot, Moore & Beck;Chase Tower, Suite 3250, 111 Monument Circle, Indianapolis, IN, 46204, US

(73) Assignee: Infineon Technologies AG, Munich (DE)

(21) Appl. No.: 11/706,076

(22) Filed: Feb. 13, 2007

(30) Foreign Application Priority Data
Feb. 13, 2006 (EP) 06002881.8

(51) Int. Cl. H03B 1/00

(52) U.S. Cl. 327/112

(57) ABSTRACT

A circuit for reducing jitter and/or phase jump problems in a clock amplifier device due to variations in the voltage supplied to the clock amplifier device has an input terminal connected to the supply voltage to allow the circuit to sense the actual supply voltage, and an output terminal connected to an output of the clock amplifier device. The circuit is provided to draw a current from, or feed a current to, the output of the clock amplifier device via the output terminal in response to a difference between the sensed actual supply voltage and a desired supply voltage. The circuit is preferably implemented in a first stage of a CMOS inverter chain in a GPS navigator device.

### CROSS-REFERENCE TO RELATED APPLICATION

This application claims priority from European Patent Application No. 06002881.8, which was filed on Feb. 13, 2006, and is incorporated herein by reference in its entirety.

### BACKGROUND

The present invention generally relates to clock amplifiers, and more specifically the invention refers to a circuit and a method, respectively, for reducing jitter and/or phase jump problems in a clock amplifier device due to variations in the voltage supplied to the clock amplifier device.

The standard clock amplifier used in CMOS circuits is an inverter chain. The first stage in the inverter chain sets a lot of the jitter performance, especially if the clock signal has slow flanks, i.e. is sinusoidal. A problem is that the first inverter switching point is dependent on the supply voltage so any ripple on the supply voltage will lead to a modulation of the amplified clock signal. In a simple example the switching point is moving about half the supply voltage variation. This not only causes jitter, but also phase jumps, which can be disastrous for ongoing transmissions/receptions.

Solutions currently used comprise to decouple the clock amplifier with capacitors and/or to use separate supplies. The disadvantage with capacitors is that they have to be large if the voltage that varies over long periods of time is to be inhibited, thereby occupying valuable chip area. Separate supplies increase complexity and are costly.

### BRIEF SUMMARY

It is an advantage of at least some embodiments of the present invention to provide a circuit and a method, respectively, for reducing jitter and/or phase jump problems in a clock amplifier device due to variations in the voltage supplied to the clock amplifier device, which alleviate the above shortcomings and drawbacks of the current solutions.

It is in this respect a particular advantage of some embodiments to provide such a circuit, which does not require large and bulky capacitors or separate voltage supplies for the clock amplifier.

According to an aspect of the invention there is provided a circuit comprising an input terminal connected to the supply voltage to allow the circuit to sense the actual supply voltage, and an output terminal connected to an output of the clock amplifier. The circuit is provided to draw a current from, or feed a current to, the output of the clock amplifier device via the output terminal in response to a difference between the sensed actual supply voltage and a desired supply voltage.

The current is proportional to the above voltage difference and is determined so that the switching point of the clock amplifier device is adjusted to the position it would have had provided that the sensed actual supply voltage would have been identical with the desired voltage.

The circuit is preferably implemented in a first stage of a CMOS inverter chain in a GPS navigator device, although it may be used in other amplifiers and devices, such as in radio frequency receivers and transmitters and AD and DA circuits, as well as for other applications.

According to a further aspect of the invention there is provided a method comprising the steps of sensing the actual voltage supplied to a clock amplifier, calculating a difference between the sensed actual voltage supplied to the clock amplifier and a desired supply voltage, and drawing a current from, or feeding a current to, an output of the clock amplifier in response to the calculated difference between the sensed voltage supplied to the clock amplifier device and the desired supply voltage.

### BRIEF DESCRIPTION OF THE SEVERAL VIEWS OF THE DRAWING(S)

Further characteristics of the invention and advantages thereof will be evident from the detailed description of preferred embodiments of the present invention given hereinafter and the accompanying FIGS. 1-5, which are only given by way of illustration, and thus are not limitative of the present invention.

FIG. 1 illustrates a clock amplifier device including a circuit for reducing jitter and/or phase jump problems according to an embodiment of the present invention.

FIG. 2 is a diagram of output voltage versus input voltage for a known clock amplifier device for different supply voltages.

FIG. 3 is a diagram of output voltage versus input voltage for the clock amplifier device of FIG. 1 for different supply voltages.

FIGS. 4-5 illustrate example implementations of the jitter and/or phase jump reduction circuit of FIG. 1.

### DETAILED DESCRIPTION

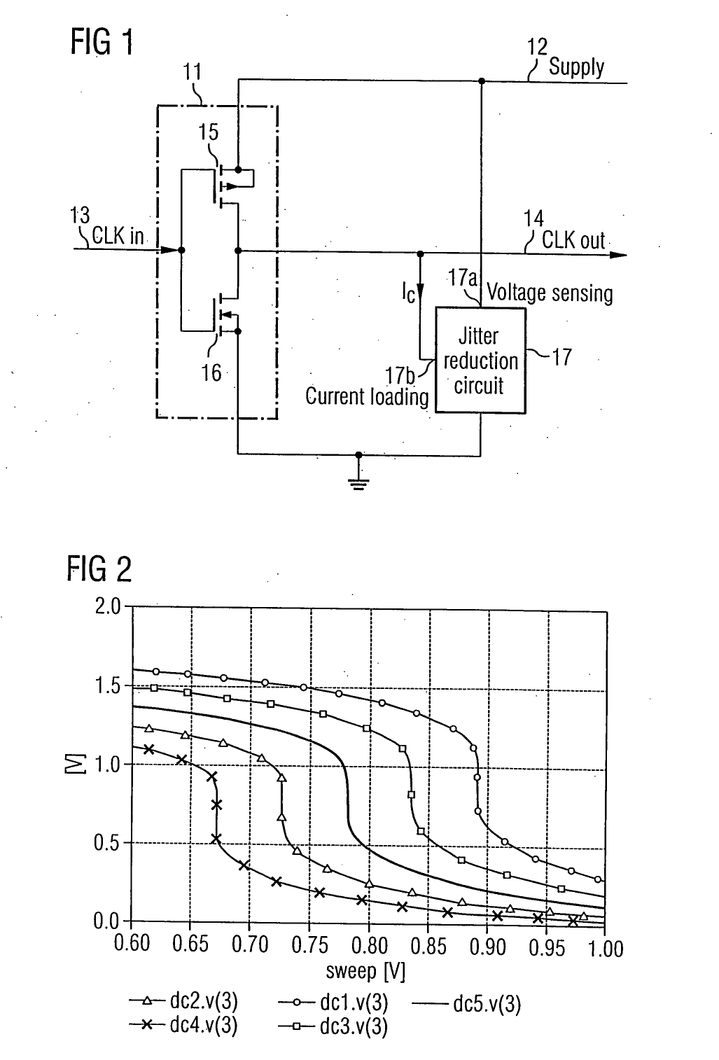

An embodiment of a clock amplifier device including a circuit for mitigating jitter and/or phase jump problems in accordance with the present invention is shown in FIG. 1. Preferably, the clock amplifier device is a monolithically integrated single-chip device.

The clock amplifier device comprises a clock amplifier circuit 11 connected to, and supplied by, a supply voltage 12. The clock amplifier circuit 11 has an input for receiving a clock input signal 13 and an output for outputting a clock output signal 14, and comprises preferably a conventional CMOS-based inverter including a PMOS transistor 15 and an NMOS transistor 16. Preferably, the CMOS-based inverter is a first of a number of inverters or inverter stages together forming an inverter chain. Inverters and inverter chains of this kind are e.g. disclosed in U.S. Pat. Nos. 4,734,597 and 5,767,728, and in U.S. Patent Pub. Nos. 2002/0075090 and 2001/0054926, the contents of which being hereby incorporated by reference.

Due to noise and other variations, e.g. caused by load pulling, in the voltage 12 supplied to the clock amplifier circuit 11 jitter and/or phase jumps may be obtained in the clock output signal 14. Therefore, in accordance with this embodiment of the present invention, a circuit 17 for reducing this jitter and phase jumps is provided. The circuit 17 comprises an input terminal 17a connected to the supply voltage 12 to allow the circuit 17 to sense the actual instantaneous voltage supplied to the clock amplifier device, i.e. all variations that occur. An output terminal 17b of the circuit 17 is connected to the output of the clock amplifier circuit 11, wherein the circuit is configured to draw a current I_{c} from, or feed a current to, the clock amplifier circuit 11 via its output terminal 17b in response to a difference between the sensed actual voltage supplied to the clock amplifier circuit 11 and a desired supply voltage.

The current I_{c} is proportional to the voltage difference according to
I_{c}=c*(V_{S}−V_{D}) (Eq. 1)
where V_{S} is the sensed actual voltage supplied to the clock amplifier circuit 11, V_{D} is the desired supply voltage (i.e. the ideal supply voltage in case no noise or variations occur in the supply voltage, and c is a constant dependent on the clock amplifier circuit 11.

The circuit 17 is effective to move or adjust the switching point of the clock amplifier circuit 11 towards the switching point obtained when the clock amplifier circuit 17 is supplied with the desired or ideal supply voltage. If the sensed actual supply voltage is higher than the desired supply voltage, i.e. V_{S}>V_{D}, a current is drawn from the clock amplifier circuit 11, and if the sensed actual supply voltage is lower than the desired supply voltage, i.e. V_{S}<V_{D}, a current is fed to the clock amplifier circuit 11.

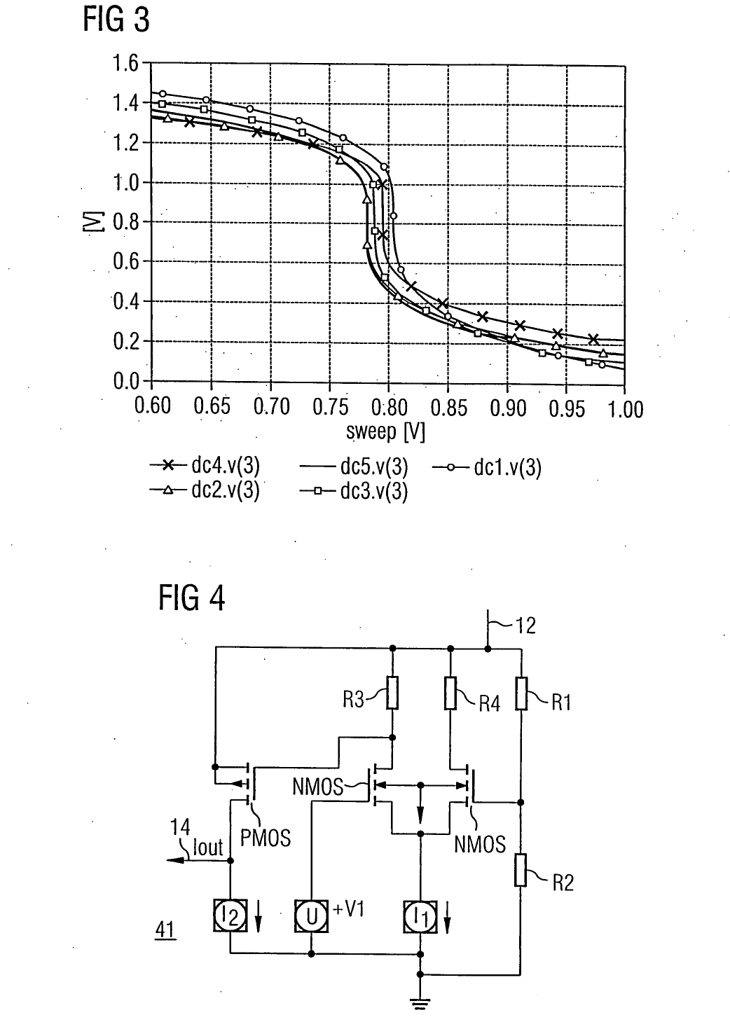

FIGS. 2-3 are diagrams of output voltage versus input voltage for a clock amplifier without the circuit 17, and for the clock amplifier device of FIG. 1, i.e. with the circuit 17, respectively, for different supply voltages. The solid line corresponds to a supply voltage of 1.5 V, which is chosen as the desired or ideal supply voltage, the x-marked curve corresponds to a supply voltage of 1.3 V, the curve with triangles corresponds to a supply voltage of 1.4 V, the curve with squares corresponds to a supply voltage of 1.6 V, and the curve with circles corresponds to a supply voltage of 1.7 V.

In FIG. 2 it can be seen that the switching point is quite different for the different supply voltages. For the desired or ideal supply voltage of 1.5 V, the switching point is at an input voltage of about 0.78 V, whereas for the most extreme supply voltages, 1.3 V and 1.7 V, the switching points are at input voltages of about 0.67 V and 0.89 V.

In FIG. 3 it can be seen that the switching points are very similar (i.e. varies from 0.78 V to 0.81 V) almost independent of the supply voltage. The value of the constant c may be calculated analytically or may be retrieved by means of simulations.

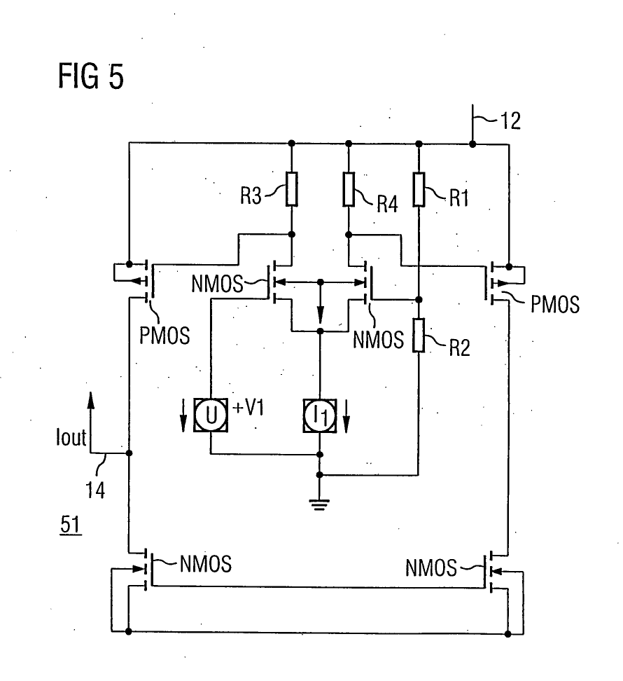

The circuit 17, having a transfer function according to Eq. 1, may be designed in a plurality of manners readily known to a person skilled in the art. Nevertheless, two exemplary implementations are shown in FIGS. 4 and 5. The connections to the supply voltage 12 and to the clock output 14 are indicated. R1, R2, R3, and R4 denote resistors, NMOS and PMOS denote transistors of NMOS and PMOS type, respectively, U denotes a voltage source, and I₁ and I₂ denote current sources. The selection of appropriate electrical parameters of the components above is readily made or retrieved by a person skilled in the art.

This embodiment of the invention can be implemented in a clock amplifier of a GPS navigator device since the jitter and phase jumps seem to be particularly troublesome there. However, the invention is not limited to such implementation, but may be implemented in any kind of device or application using a clock amplifier circuit having similar problems with jitter and phase jumps.

In the preceding detailed description, the invention is described with reference to specific exemplary embodiments thereof. Various modifications and changes may be made thereto without departing from the broader spirit and scope of the invention as set forth in the claims. The specification and drawings are, accordingly, to be regarded in an illustrative rather than a restrictive sense.

While this invention has been described in terms of at least some embodiments, there are alterations, permutations, and equivalents which fall within the scope of this invention. It should also be noted that there are many alternative ways of implementing the methods and compositions of the present invention. It is therefore intended that the following appended claims be interpreted as including all such alterations, permutations, and equivalents as fall within the true spirit and scope of the present invention.

1. A circuit for reducing jitter and/or phase jump problems in a clock amplifier device due to variations in the voltage supplied to the clock amplifier device, wherein said circuit comprises:
an input terminal connected to said voltage supplied to the clock amplifier device to allow said circuit to sense the actual voltage supplied to the clock amplifier device, and
an output terminal connected to an output of said clock amplifier device, wherein
said circuit is provided to draw a current from, or feed a current to, the output of said clock amplifier device via said output terminal in response to a difference between the sensed actual voltage supplied to the clock amplifier device and a desired supply voltage.

2. The circuit of claim 1, wherein said circuit is provided to draw a current from, or feed a current to, the output of said clock amplifier device, which is proportional to the difference between the sensed actual voltage supplied to the clock amplifier device and a desired supply voltage to thereby move a switching point of said clock amplifier device towards the switching point obtained if said clock amplifier device would have been supplied with the desired supply voltage.

3. The circuit of claim 1, wherein said clock amplifier device is an inverter chain and said circuit is implemented in a first stage of said chain.

4. The circuit of claim 1, wherein said circuit is implemented in a GPS navigator device.

5. The circuit of claim 1, wherein said circuit is implemented in a radio frequency receiver or transmitter.

6. The circuit of claim 1, wherein said circuit is implemented in an AD or DA circuit, preferably a high precision AD or DA circuit.

7. A method for reducing jitter and/or phase jump problems in a clock amplifier device due to variations in the voltage supplied to the clock amplifier device, comprising:
sensing the actual voltage supplied to the clock amplifier device,
calculating a difference between the sensed actual voltage supplied to the clock amplifier device and a desired supply voltage, and
drawing a current from, or feeding a current to, an output of said clock amplifier device in response to said calculated difference between the sensed voltage supplied to the clock amplifier device and the desired supply voltage.

8. The method of claim 7, wherein said current drawn from, or fed to, the output of said clock amplifier device, is proportional to the difference between the sensed actual voltage supplied to the clock amplifier device and a desired supply voltage to thereby move a switching point of said clock amplifier device towards the switching point obtained if said clock amplifier device would have been supplied with the desired supply voltage.

9. The method of claim 7, wherein said method is performed in a first stage of an inverter chain.

10. The method of claim 7, wherein said method is performed in a GPS navigator device.

11. An arrangement, comprising:
a clock amplifier circuit having a supply terminal, an input terminal, and an output terminal;
a first circuit coupled to the clock amplifier circuit, the first circuit configured to draw a current from, or feed a current to, the output terminal of the clock amplifier circuit in response to a difference between a sensed actual voltage at the supply terminal and a desired supply voltage.

12. The arrangement of claim 11, wherein the clock amplifier circuit includes a first transistor coupled the input terminal, the output terminal and the supply terminal, and a second transistor coupled to the input terminal, the output terminal, and a reference terminal.

13. The arrangement of claim 11, wherein the clock amplifier circuit includes a CMOS-based inverting amplifier circuit.

14. The arrangement of claim 13, wherein the clock amplifier circuit includes a first transistor coupled the input terminal, the output terminal and the supply terminal, and a second transistor coupled to the input terminal, the output terminal, and a reference terminal.

15. The arrangement of claim 14, wherein the first circuit is configured to draw a current from, or feed a current to, the output terminal, in a manner that is proportional to the difference between the sensed actual voltage at the supply terminal and the desired supply voltage.

16. The arrangement of claim 11, wherein the arrangement is implemented in a GPS navigator device.

17. The arrangement of claim 11, wherein the arrangement is implemented in a radio frequency receiver or transmitter.

18. The arrangement of claim 11, wherein said circuit is implemented in an AD or DA circuit, preferably a high precision AD or DA circuit.

19. The arrangement of claim 13, wherein the first circuit is configured to draw a current from, or feed a current to, the output terminal, in a manner that is proportional to the difference between the sensed actual voltage at the supply terminal and the desired supply voltage.

20. The arrangement of claim 11, wherein the first circuit is configured to draw a current from, or feed a current to, the output terminal, in a manner that is proportional to the difference between the sensed actual voltage at the supply terminal and the desired supply voltage.
